(19) United States
(12) Patent Application Publication
(10) Pub. No.: US 2006/0189292 A1
(43) Pub. Date: Aug. 24, 2006

(54) Electronic circuit device

(75) Inventors: Masanori Ueda, Yokohama (JP); Osamu Kawachi, Yokohama (JP); Kenya Hashimoto, Funabashi (JP)

Correspondence Address: ARENT FOX PLLC, 1050 CONNECTICUT AVENUE, N.W., SUITE 400, WASHINGTON, DC, 20036, US

(73) Assignee: Fujitsu Media Devices Limited

(21) Appl. No.: 11/349,342

(22) Filed: Feb. 8, 2006

(30) Foreign Application Priority Data
Feb. 8, 2005 (JP) 2005-031983

(51) Int. Cl. H04B 1/10; H03H 9/00; H04B 1/16

(52) U.S. Cl. 455/307; 333/193; 455/339

(57) ABSTRACT

An electronic circuit device includes filters, and a 90-degree hybrid circuit connected to the filters. The 90-degree hybrid circuit may have first and second output terminals. The first terminal of the 90-degree hybrid circuit is connected to an input terminal of one of the filters, and the second terminal thereof is connected to an input terminal of another one of the filters. The 90-degree hybrid circuit may include at least one of phase lines and lumped constant circuit elements.

### BACKGROUND OF THE INVENTION

1. Field of the Invention

The present invention generally relates to electronic circuit devices, and more particularly, to an electronic circuit device with a high-frequency filter.

2. Description of the Related Art

High-frequency filters are employed in radio-frequency transmitters or receivers in portable phones or the like, and are designed to have high filter performance. An acoustic wave filter is used as the high-frequency filter. The acoustic filter may be a surface acoustic wave (SAW) filter or a film-bulk acoustic resonator (FBAR) filter. The SAW filter has a compact size, a light weight and an excellent shape factor. The FBAR filter has excellent filter performance in higher frequencies and may be downsized. The high-frequency filter employed in the transmitter may be connected to the input or output terminal of a high-power amplifier circuit or the both, and functions to cut off the frequency components other than desired frequencies. The high-frequency filter employed in the receiver may be connected to the input or output terminal of a low-noise amplifier circuit or the both, and allows only desired frequency components to a nexi-stage circuit, which may be an amplifier circuit or a mixer. Japanese Patent Application Publication No. 2004-104449 discloses this kind of high-frequency filter.

However, the filter connected to the input terminal of the amplifier circuit degrades the amplifying performance if the output side of the filter has a large return loss S22. Similarly, the filter connected to the output terminal of the amplifier circuit degrades the amplifying performance if the input side of the filter has a large return loss S11.

Conventionally, an impedance matching circuit or an isolator is additionally employed in order to reduce the return loss of the filter.

However, the use of the impedance matching circuit raises a problem such that the frequency at which impedance matching is available depends on the circuit constants. It is thus difficult to totally reduce the return loss over the used frequency range. The use of the isolator makes it difficult to achieve downsizing due to the presence of a magnetic substance.

### SUMMARY OF THE INVENTION

The present invention has been made in view of the above-mentioned circumstances, and provides an electronic circuit device having a reduced return loss, higher performance, a broader frequency range and a smaller size.

According to an aspect of the present invention, there is provided an electronic circuit device including: filters; and a 90-degree hybrid circuit connected to the filters. A signal applied to the first terminal of the 90-degree hybrid circuit is prevented from passing therethrough, being reflected by the filter and returning the first terminal. It is thus possible to reduce the return loss and to provide an electronic circuit device having a reduced return loss, higher performance, a broader frequency range and a smaller size.

According to another aspect of the present invention, there is provided an electronic circuit device including: a first filter having input and output terminals; a second filter having input and output terminals; a first 90-degree hybrid circuit having first and second input terminals, wherein the output terminal of the first filter is connected to the first input terminal of the 90-degree hybrid circuit, and the output terminal of the second filter is connected to the second input terminal of the 90-degree hybrid circuit. This electronic circuit device may further include a second 90-degree hybrid circuit having third and fourth input terminals, wherein the third output terminal of the second 90-degree hybrid circuit is connected to the input terminal of the first filter, and the fourth input terminal of the second 90-degree hybrid circuit is connected to the input terminal of the second filter.

### BRIEF DESCRIPTION OF THE DRAWINGS

Other objects, features and advantages of the present invention will become more apparent from the following detailed description when read in conjunction with the accompanying drawings, in which:

FIG. 1 is a graph of the result of a simulation of the power added efficiency as a function of input power (dBm) in a case where the return loss S22 of a filter connected to the input side of a high-power amplifier circuit in the portable phone terminal changes from −5 dB to −35 dB for every 5 dB;

FIG. 2 is a graph of the result of a simulation of the power added efficiency as a function of input power (dBm) in a case where the return loss S11 of a filter connected to the output side of a high-power amplifier circuit in the portable phone terminal changes from −5 dB to −35 dB at the step of 5 dB.

FIG. 3 is a block diagram illustrating functions of a 90-degree hybrid circuit;

FIG. 4 shows a configuration of the 90-degree hybrid circuit composed of ¼ wavelength lines;

FIG. 5 shows another configuration of the 90-degree hybrid circuit composed of lumped parameter circuit elements;

FIG. 6 is a block diagram illustrating the principles of a first embodiment of the present invention;

FIG. 7 is a circuit diagram of the first embodiment of the present invention;

FIG. 8 is an exploded perspective view of the first embodiment of the present invention;

FIG. 9 is a graph of the frequency dependence of the return loss S22 in the first embodiment of the present invention;

FIG. 10 is an exploded perspective view of a variation of the first embodiment of the present invention;

FIG. 11 is a circuit diagram of a second embodiment of the present invention;

FIG. 12 is a graph of the power added efficiency that depends on input power in the second embodiment of the present invention;

FIG. 13 is a block diagram of a third embodiment of the present invention;

FIG. 14 is a graph of the power added efficiency that depends on input power in the third embodiment of the present invention; and

FIG. 15 is a block diagram of a fourth embodiment of the present invention.

### DESCRIPTION OF THE PREFERRED EMBODIMENTS

A description will now be given of a problem that arises from a situation in which a filter associated with a high-power amplifier circuit in portable terminal equipment such as a portable phone terminal has a large return loss.

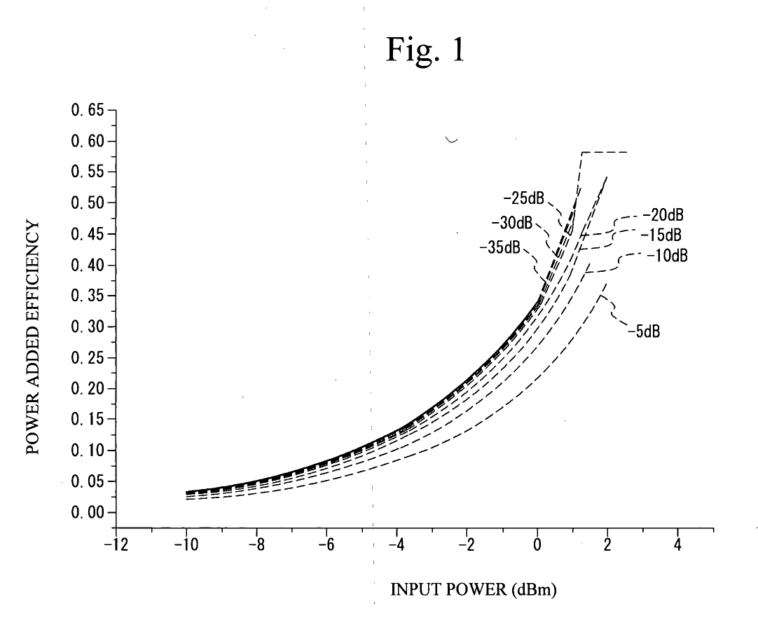

FIG. 1 is a graph of the result of a simulation of the power added efficiency as a function of input power (dBm) in a case where the return loss S22 of the filter connected to the input side of the high-power amplifier circuit in the portable phone terminal changes from −5 dB to −35 dB for every 5 dB. The figures attached to the curves are the values of the return loss S22. It can be seen from the graph that the power added efficiency decreases as the return loss S22 increases.

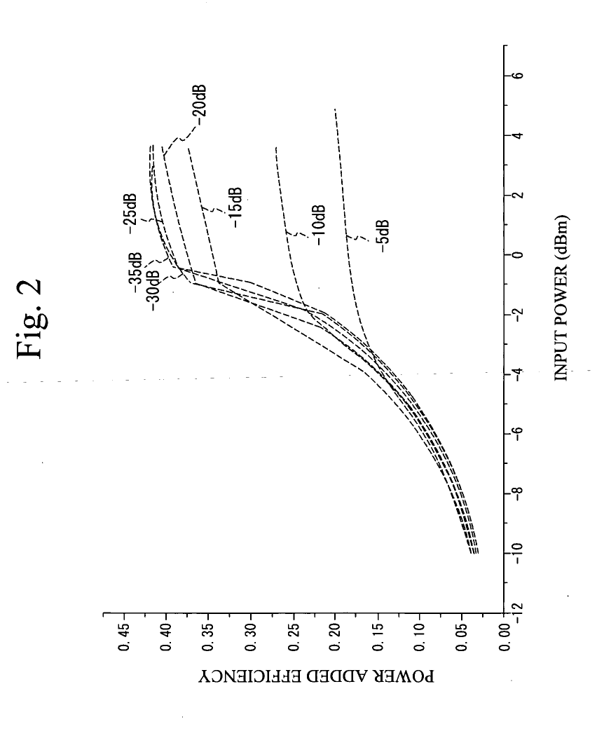

FIG. 2 is a graph of the result of a simulation of the power added efficiency as a function of input power (dBm) in a case where the return loss S11 of the filter connected to the output side of the high-power amplifier circuit in the portable phone terminal changes from −5 dB to −35 dB at the step of 5 dB. The figures attached to the curves are the values of the return loss S11. It can be seen from the graph that the power added efficiency decreases as the return loss S11 increases.

The above simulation results show that the performance of the amplifier circuit can be improved by reducing the return losses of the filter.

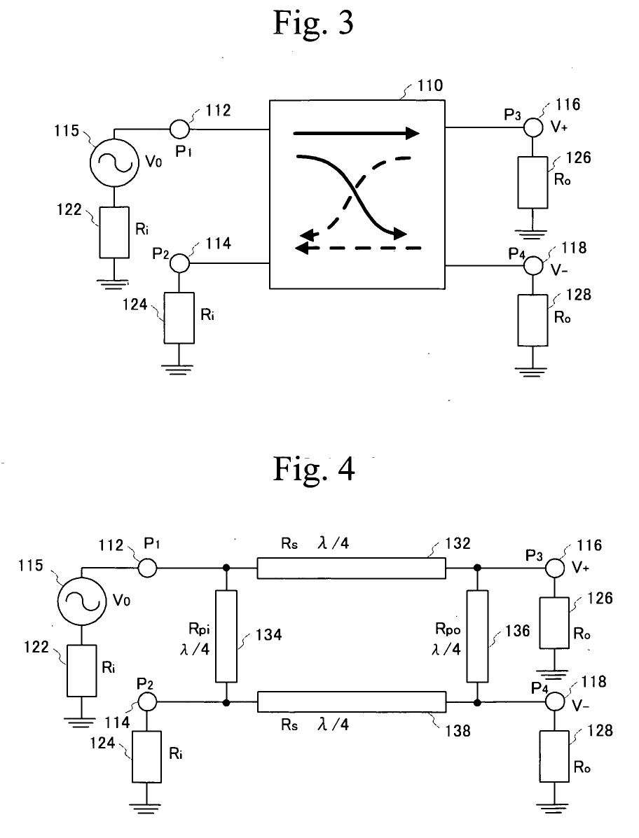

A description will now be given, with reference to FIG. 3, of the operation of a 90-degree hybrid circuit. A 90-degree hybrid circuit 110 has a first input terminal 112, a second input terminal 114, a first output terminal 116, and a second output terminal 118. An input signal source 115 is connected to the first input terminal 112, and is grounded via an impedance circuit 122. The second input terminal 114, the first output terminal 116 and the second output terminal 118 are grounded via impedance circuits 124, 126 and 128, respectively.

A signal applied to the first input terminal 112 of the 90-degree hybrid circuit 110 is equally divided to two so that the half of the input power is output to the first output terminal 116, and the other half is output to the second output terminal 118, as indicated by arrows of solid lines. At that time, the signal output to the second output terminal 118 has a phase that lags behind the signal output to the first output terminal 116. Signals reflected by the output terminals 116 and 118 of the hybrid circuit 110 have an identical power and a 180-degree out-of-phase relation in which the phase of the signal at the second output terminal 118 lags behind the signal at the first output terminal 116. In this case, the reflected signals travel to only the second input terminal 114, and does not travel to the first input terminal 112, as indicated by arrows of broken lines in FIG. 3.

The 90-degree hybrid circuit 110 may be realized by a ¼ wavelength (λ) line, which functions as a phase shifter, in which one wavelength is the wavelengths of the signals applied to the 90-degree hybrid circuit 110. FIG. 4 shows a configuration of the 90-degree hybrid circuit 110 composed of ¼ wavelength lines 132, 134, 136 and 138. The ¼ wavelength line 132 is connected to the first input terminal 112 and the first output terminal 116. The ¼ wavelength line 134 is connected to the first and second input terminals 112 and 114. The ¼ wavelength line 136 is connected between the first and second output terminals 116 and 118. The ¼ wavelength line 138 is connected between the second input terminal 114 and the second output terminal 128.

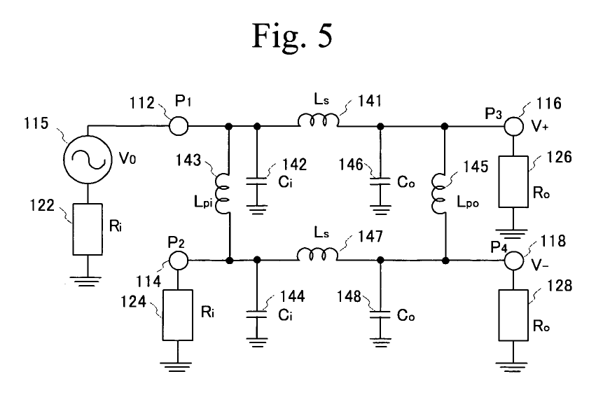

The 90-degree hybrid circuit 110 may be formed by an inductor and a capacitor, these elements being lumped parameter circuit elements. FIG. 5 shows a configuration of the 90-degree hybrid circuit composed of lumped parameter circuit elements. The first and second input terminals 112 and114 of the 90-degree hybrid circuit 110 are respectively grounded via capacitors 142 and 144, and the first and second output terminals 116 and 118 are respectively grounded via capacitors 146 and 148. An inductor 141 is connected between the first input terminal 112 and the first output terminal 116. An inductor 143 is connected between the first and second input terminals 112 and 114. An inductor 145 is connected between the first and second output terminals 116 and 118. An inductor 147 is connected between the second input terminal 114 and the second output terminal 118.

As described above, the 90-dgree hybrid circuit 110 may be realized by either phase lines or lumped parameter circuit elements, and may be a combination of phase lines and lumped parameter circuit elements.

A description will now be given of a filter circuit having 90-degree hybrid circuits and filters in accordance with a first embodiment of the present invention.

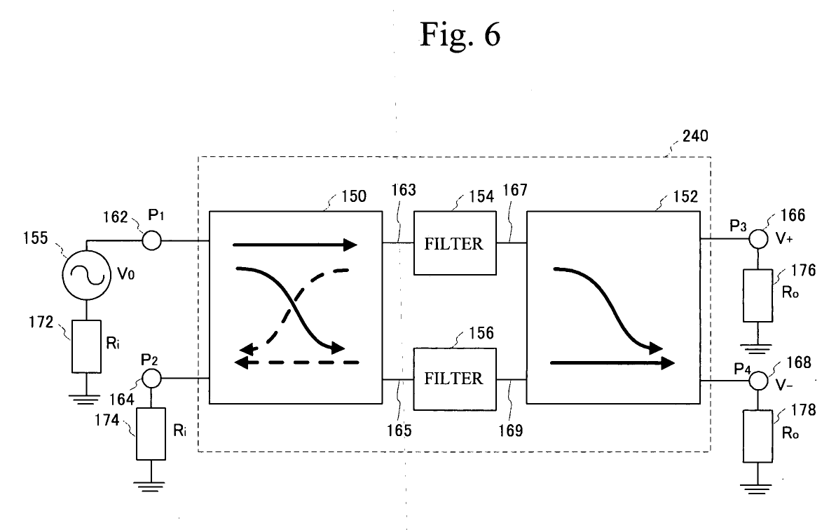

FIG. 6 shows the principles of the first embodiment. The filter circuit of the first embodiment is equipped with a first 90-degree hybrid circuit 150, a second 90-degree hybrid circuit 152, a first filter 154, and a second filter 156. First and second output terminals 163 and 165 of the first hybrid circuit 150 are connected to input terminals of the filters 154 and 156, respectively. Input terminals of the second hybrid circuit 152 are connected to the output terminals of the filters 154 and 156, respectively.

A case where a signal is applied to the first input terminal 162 will now be considered. A high-frequency signal source 155 is connected to the first input terminal 162 of the first 90-degree hybrid circuit 150, and is grounded via an impedance circuit 172. The second input terminal 164 of the first hybrid circuit 150 are grounded via an impedance circuit 174. The first output terminal 166 of the second hybrid circuit 152 is grounded via an impedance circuit 176. The second output terminal 168 of the second hybrid circuit 152 is grounded via an impedance circuit 178.

The input signal applied to the first input terminal 162 of the hybrid circuit 150 is equally divided into two so that the half of the input power is output via the first output terminal 163 of the 90-degree hybrid circuit 150, and the other half is output via the second output terminal 165 thereof, as indicated by arrows of solid lines. The signal available at the second output terminal 165 lags behind the signal available at the first output terminal 163.

Signals reflected by the first filter 154 and the second filter 156 travel to the first output terminal 163 and the second output terminal 165. As has been described with reference to FIG. 3, the signals reflected by the filters little ravel to the first input terminal 162, and travel to the second input terminal 164, as indicated by arrows of broken lines. Then, the signals flow to the ground and are consumed. The reflected wave of the input signal applied to the first input terminal 162 is little output thereto, so that the return loss S11 can be drastically reduced.

The signals applied to the first and second filters 154 and 156 are filtered thereby, and the respective desired frequency components are allowed to pass therethrough. The signals from the first and second filters 154 and 156 are respectively applied to the first and second input terminals 167 and 169 of the second hybrid circuit 152. These signals have an identical power and a phase difference equal to 90 degrees in which the signal applied to the second input terminal 169 lags behind the signal applied to the first input terminal 167. A signal having combined power of the two input signals is output via the second output terminal 168 of the second hybrid circuit 152, as indicated by arrows of solid lines.

The signal applied to the first input terminal 162 is filtered by the first and second filters 154 and 156, and only the desired frequency components are output to the second output terminal 168, so that the filtering function can be implemented.

Another case where a signal is applied to the second output terminal 168 of the second hybrid circuit 152 will now be considered. The signals reflected by the first and second filters 154 and 156 are little output to the second output terminal 168, so that the return loss S22 can be reduced. Consequently, the filter circuit of the first embodiment has both reduced return losses S11 and S22.

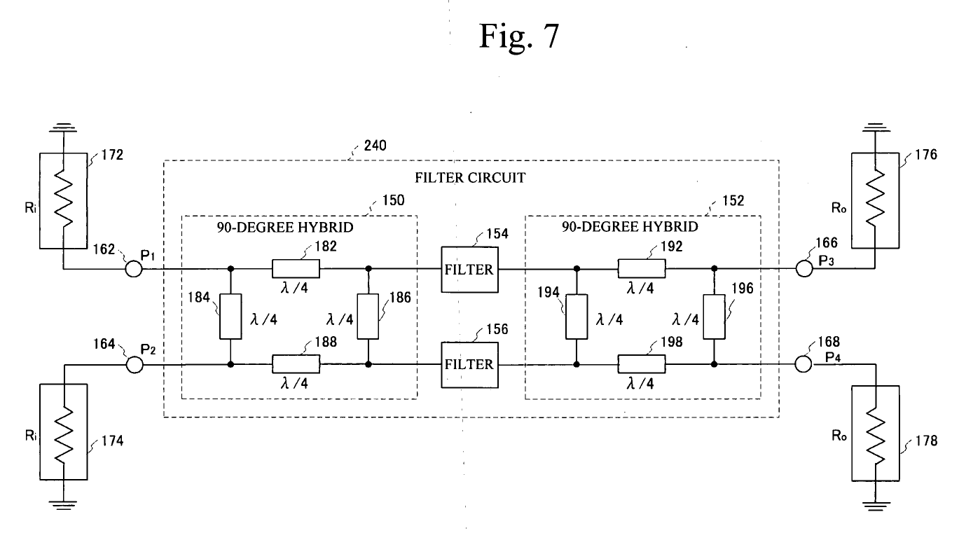

FIG. 7 is a circuit diagram of a filter circuit device in accordance with the first embodiment of the present invention. The filter circuit 240 has the first 90-degree hybrid circuit 150, the second 90-degree hybrid circuit 152, the first filter 154 and the second filter 156. The first 90-degree hybrid circuit 150 is composed of ¼ wavelength lines 182, 184, 186 and 188, and the second 90-degree hybrid circuit 152 is composed of ¼ wavelength lines 192, 194, 196 and 198. In each of the 90-degree hybrid circuits 150 and 152, the ¼ wavelength lines are connected as shown in FIG. 4. The first and second filters 154 and 156 are FBAR filters.

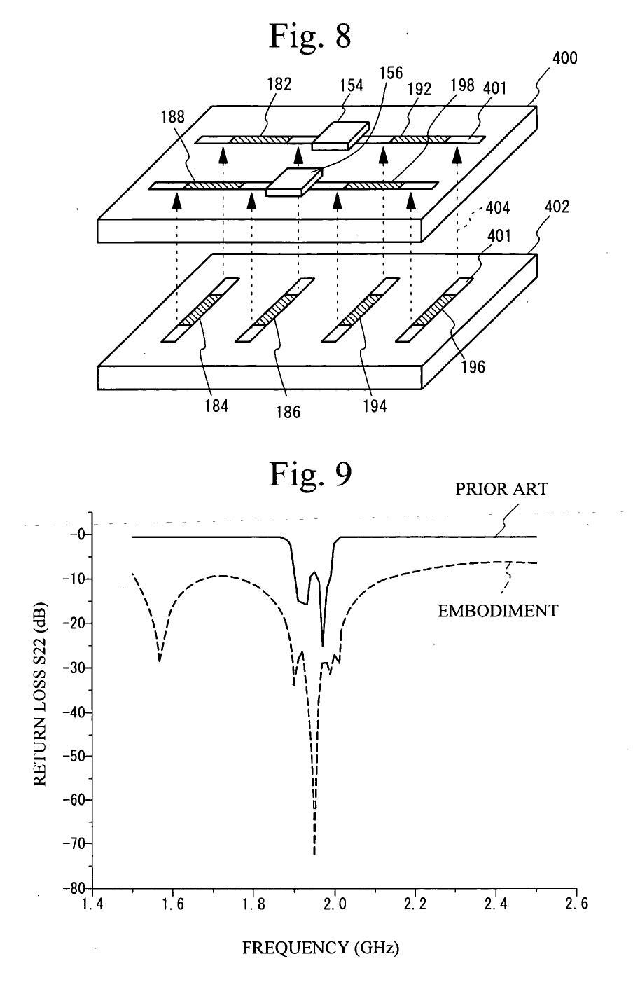

FIG. 8 is an exploded perspective view of the filter circuit device 140, which the phase lines are formed on ceramic substrates that form a multilayer structure and the filters are mounted thereon. The first and second filters 154 and 156 are mounted on a first ceramic substrate 400, which is a part of the multilayer structure. The ¼ wavelength lines 182 and 188 used to form the first 90-degree hybrid circuit 150 are formed on the first ceramic substrate 400, and ¼ wavelength lines 192 and 198 used to form the second 90-degree hybrid circuit 152 are mounted thereon. The multilayer structure has a second ceramic substrate 402. The ¼ wavelength lines 184 and 186 of the first 90-degree hybrid circuit 150 are formed on the second ceramic substrate 402, and the ¼ wavelength lines 194 and 196 of the second 90-degree hybrid circuit 152 are formed thereon. Reference numerals 401 indicate transmission lines used to connect the filters and the ¼-wavelength lines formed on the first and second ceramic substrates 400 and 402.

Via holes for making connections are formed in the first ceramic substrate 400 and are located at positions indicated by 404. The first and second ceramic substrates 400 and 402 are stacked so that the phase lines formed thereon are brought into contact with each other. The ceramic substrates to be laminated may be high temperature co-fired ceramic (HTCC) or low temperature co-fired ceramic (LTCC). The ceramic laminate may be another multilayered substrate or printed circuit board.

The return loss of the filter circuit device in accordance with the first embodiment was evaluated as follows. Turning to FIG. 7 again, the first and second input terminals 162 and 164 and the first and second output terminals 166 and 168 were grounded via impedance circuits 172, 174, 176 and 178, respectively, each of which had an impedance of 50Ω.

FIG. 9 is a graph that shows the return loss S22 (dB) depends on the frequency (GHz). In FIG. 9, “PRIOR ART” indicates the return loss S22 observed when the filter circuit is composed of FBAR filters only, and “EMBODIMENT” indicates the return loss S22 for the above-mentioned first embodiment. The filters are designed to have a pass band ranging from 1.92 GHz to 1.98 GHz. The return loss S22 of the conventional filter is approximately −10 dB in the pass band, whereas the return loss S22 of the first embodiment filter is as large as approximately 30 dB. The first embodiment can realize the filter circuit with the return loss S22 being reduced by approximately 20 dB.

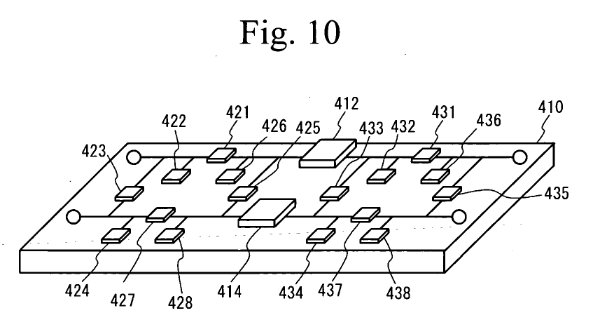

A variation of the first embodiment will now be described. The variation employs lumped parameter circuit elements of inductors and capacitors for the 90-degree hybrid circuits. FIG. 10 shows this variation. A substrate 410 may, for example, be a ceramic substrate or printed circuit board. A first filter 412 and a second filter 414 are mounted on the substrate 410. On the substrate 410, provided are inductors 421, 423, 425 and 427 and capacitors 422, 424, 426 and 428 of the first 90-degree hybrid circuit 150. Similarly, on the substrate 410, provided are inductors 431, 433, 435 and 437 and capacitors 432, 434, 436 and 438 of the second 90-degree hybrid circuit 152. The capacitors 422, 424, 426, 428, 432, 434, 436 and 438 are grounded through via holes formed in the substrate 410. The inductors and capacitors may be chip inductors and chip capacitors.

As described above, the 90-degree hybrid circuits employed in the first embodiment may be composed of either phase lines or lumped constant circuit elements. The phase lines may be formed on a multilayered substrate such as a high temperature co-fired ceramic (HTCC) substrate or a low temperature co-fired ceramic (LTCC) substrate, or a printed circuit board. The lumped parameter circuit elements may be discrete components such as chip inductors or chip capacitors or may be formed by using a layer or layers of the multilayered substrate. The 90-degree hybrid circuits may be composed of both phase lines and lumped parameter circuit elements.

A description will now be given of a second embodiment of the present invention that includes the filter circuit of the first embodiment and a high-power amplifier circuit, in which the filter circuit is connected to the input side of the high-power amplifier circuit.

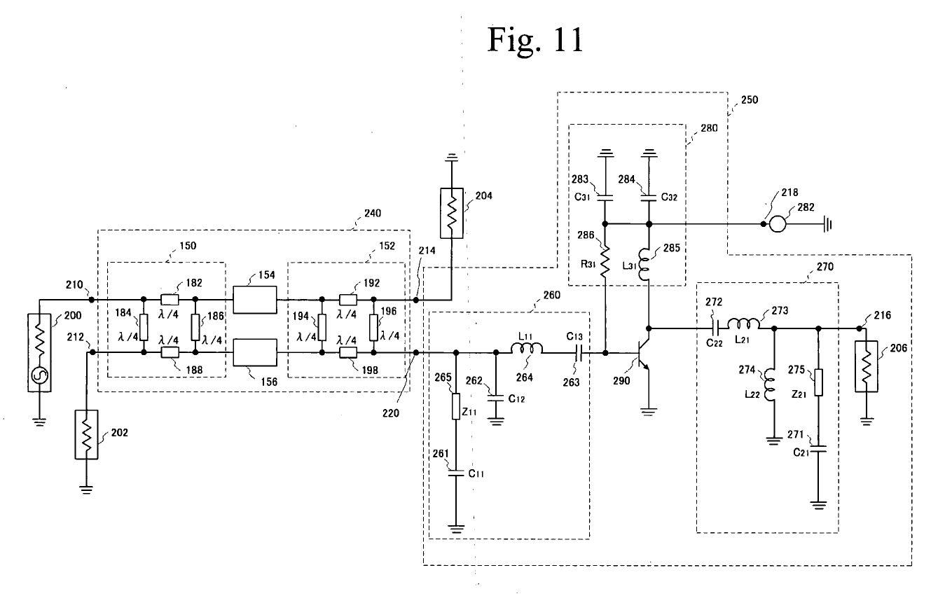

FIG. 11 is a circuit diagram of a filter circuit device in accordance with the second embodiment. The device shown in FIG. 11 employs the aforementioned filter circuit 240 shown in FIG. 7. An output terminal 220 of the filter circuit 240 is connected to an input terminal of a high-power amplifier circuit 250. The amplifier circuit 250 is composed of an interstage matching circuit 260, an output-side matching circuit 260, an output-side matching circuit 270, and a transistor 290.

The output terminal 220 of the filter circuit 240 is input to the interstage matching circuit 260, which has an output terminal connected to the base of the transistor 290. The interstage matching circuit 260 functions to match the input impedance of the high-power amplifier circuit 250 with the transistor 290. The interstage matching circuit 260 grounds the input terminal through a series circuit of an impedance element 265 and a capacitor 261, and grounds the input terminal through a capacitor 262. Further, the interstage matching circuit 260 couples its input terminal with the base of the transistor 290 through a series circuit of an inductor 264 and a capacitor 263.

A power supply circuit 280 converts a voltage supplied from a power source 282 to a desired voltage, and supplies it to the base and collector of the transistor 290. The power supply circuit 280 is configured as follows. A power supply terminal 218 of the power source 282 is grounded via capacitors 283 and 284 connected in parallel. The terminal 218 is coupled with the base of the transistor 290 via a resistor 286, and is coupled with the collector via an inductor 285.

The emitter of the transistor 290 is grounded. The transistor 290 amplifies a signal applied to the base, and outputs an amplified signal via the collector. The collector of the transistor 290 is connected to the output-side matching circuit 270.

The output-side matching circuit 270 matches the output impedance of the high-power amplifier circuit 250 with the transistor 290. The output-side matching circuit 270 is configured as follows. The input terminal of the matching circuit 270 is coupled with the output terminal thereof via a capacitor 272 and an inductor 273. The output terminal of the matching circuit 270 is grounded via an inductor 274, and is further grounded via a series circuit of an impedance element 275 and a capacitor 271.

The power added efficiency of the filter circuit device shown in FIG. 11 according to the second embodiment was measured. In the measurement, a signal source 200 was connected to a first input terminal 210 of the filter circuit 240. A second input terminal 212 of the filter circuit 240 was grounded via an impedance circuit 202. A first output terminal 214 of the filter circuit 240 is grounded via an impedance circuit 204, and the output terminal of the output-side matching circuit 270 is grounded via an impedance circuit 206. The power source 282 was connected to the power supply circuit 280.

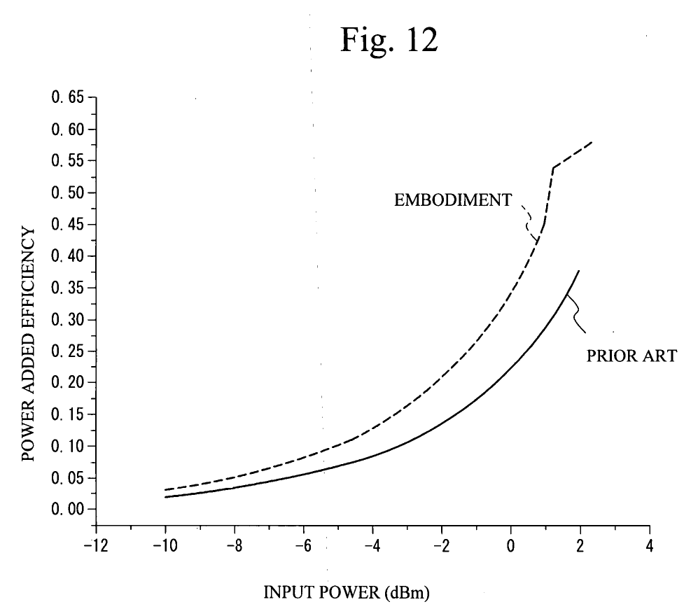

FIG. 12 is a graph of the experimental results of the power added efficiency as a function of input power (dBm) for the prior art and the second embodiment. The “PRIOR ART” shows the experimental result for a filter equipped with the FBAR filters only. The “EMBODIMENT” shows the experimental result for a filter in accordance with the second embodiment. The power added efficiency of the second embodiment is higher than that of the prior art over all input powers. Particularly, the power added efficiency is much more improved as the input power increases. This is because the return loss S22 of the filter circuit 240 is improved.

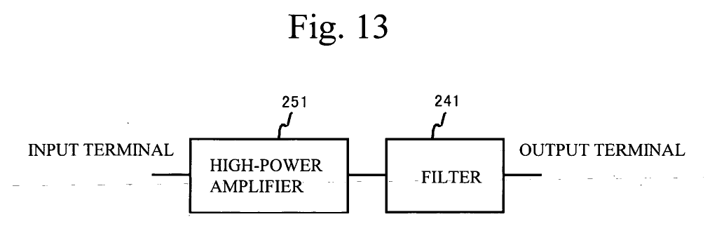

A description will now be given of a third embodiment of the present invention in which a filter circuit is connected to the output terminal of a high-power amplifier circuit for the portable phone terminal. Referring to FIG. 13, the input terminal of a filter circuit 241 is connected to the output terminal of a high-power amplifier circuit 251.

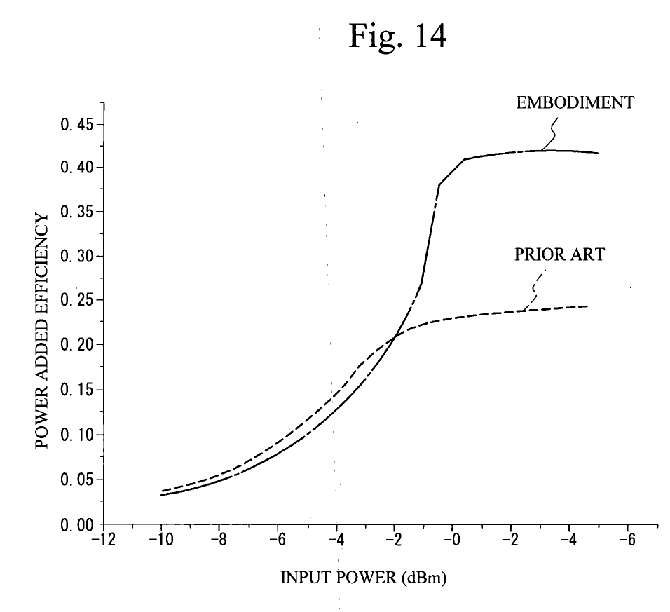

FIG. 14 is a graph of the experimental results of the power added efficiency as a function of input power (dBm) for the prior art and the third embodiment. The “PRIOR ART” shows the experimental result for a filter equipped with the FBAR filters only. The “EMBODIMENT” shows the experimental result for a filter in accordance with the third embodiment. The power added efficiency of the third embodiment is higher than that of the prior art over relatively high input powers. Particularly, the power added efficiency is much more improved as the input power increases. This is because the return loss S11 of the filter circuit 241 is improved.

In the second and third embodiments, the filter circuit is connected to either the input terminal or the output terminal of the high-power amplifier circuit. Alternatively, the filter circuits of the first embodiment may be connected to both the input and output terminals of the high-power amplifier circuit. This arrangement further improves the performance of the high-power amplifier circuit.

It is also possible to connect the filter circuit of the first embodiment to the input or output side of the low-noise amplifier circuit or the both sides thereof. This arrangement improves the performance of the low-noise amplifier circuit.

An electronic circuit device that includes the aforementioned amplifier circuit and the filter circuit may be packaged as a single module, or multiple packages mounted on a circuit board.

A description will now be given of a fourth embodiment, which has filters, a 90-degree hybrid circuit and mixers, wherein the output terminals of the mixers are connected to the input terminals of the filters. The fourth embodiment is an up converter, which receives an intermediate frequency (IF) signal and a local oscillation (LO) signal, and outputs a resultant signal. This resultant output signal has a frequency ω_{RF} equal to of ωᵢ+ω_{LO} where ωᵢ denotes the frequency of the IF signal, and ω_{LO} is the frequency of the LO signal. Simultaneously, the up converter generates the signal of the frequency equal to ωᵢ−ω_{LO}. However, this frequency component is unnecessary. The fourth embodiment is intended to suppress the frequency component ωᵢ−ω_{Lo} and reduce the return loss so that the performance of the up converter can be improved.

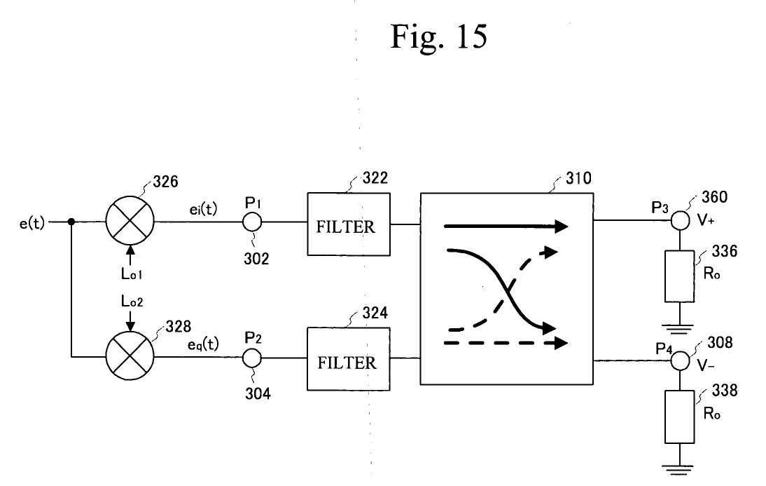

FIG. 15 is a block diagram of the up converter in accordance with the fourth embodiment of the present invention. The output terminals of a first mixer 326 and a second mixer 328 are connected to input terminals 302 and 304 of a first filter 322 and a second filter 324, respectively. The output terminals of the first and second filters 322 and 324 are connected to first and second input terminals of a 90-degree hybrid circuit 310. A first output terminal 360 and a second output terminal 308 of the 90-degree hybrid circuit are grounded via impedance circuits 336 and 338, respectively.

An input signal e(t) of the IF is applied to the first and second mixers 326 and 328, which receives LO signals LO1 and L02. The LO signal LO2 leads to LO1 by 90 degrees. The first and second mixers 326 and 328 output signals eᵢ(t) and e_{q}(t) in which e_{q}(t) leads to eᵢ(t) by 90 degrees. The signals e_{q}(t) and eᵢ(t) pass through the first and second filters 322 and 324, respectively, and are then applied to the 90-degree hybrid circuit 310, which outputs the RF signal with the frequency component ωᵢ−ω_{LO} being suppressed.

The output terminals of the first and second filters 322 and 324 are respectively connected to the input terminals of the 90-degree hybrid circuit 310. It is thus possible to reduce the return loss S22 as in the aforementioned case. This improves the performance of the up converter. The second embodiment may be applied to a down converter.

The present invention is not limited to the specifically described embodiments, but other embodiments, variation and modifications may be made without departing from the scope of the present invention.

The present application is based on Japanese Patent Application No. 2005-031983 field on Feb. 8, 2005, the entire disclosure of which is hereby incorporated by reference.

What is claimed is:

1. An electronic circuit device comprising:
filters; and
a 90-degree hybrid circuit connected to the filters.

2. The electronic circuit device as claimed in claim 1, wherein:
the 90-degree hybrid circuit has first and second output terminals;
the first terminal of the 90-degree hybrid circuit is connected to an input terminal of one of the filters, and the second terminal thereof is connected to an input terminal of another one of the filters.

3. The electronic circuit device as claimed in claim 1, wherein the 90-degree hybrid circuit comprises at least one of phase lines and lumped constant circuit elements.

4. The electronic circuit device as claimed in claim 3, wherein the phase lines are ¼ wavelength line.

5. The electronic circuit device as claimed in claim 1, wherein the 90-degree hybrid circuit comprises at least one of a ceramic laminate and lumped parameter circuit elements.

6. The electronic circuit device as claimed in claim 1, wherein the filters are acoustic wave filters.

7. The electronic circuit device as claimed in claim 1, further comprising an amplifier circuit, wherein a unit of the filters and the 90-degree hybrid circuit is connected to at least one of an input terminal and an output terminal of the amplifier circuit.

8. The electronic circuit device as claimed in claim 7, wherein the amplifier circuit includes one of a high-power amplifier circuit and a low-noise amplifier circuit for portable terminal equipment.

9. An electronic circuit device comprising:
a first filter having input and output terminals;
a second filter having input and output terminals;
a first 90-degree hybrid circuit having first and second input terminals,
wherein the output terminal of the first filter is connected to the first input terminal of the 90-degree hybrid circuit, and the output terminal of the second filter is connected to the second input terminal of the 90-degree hybrid circuit.

10. The electronic circuit device as claimed in claim 9, further comprising a second 90-degree hybrid circuit having third and fourth input terminals, wherein the third output terminal of the second 90-degree hybrid circuit is connected to the input terminal of the first filter, and the fourth input terminal of the second 90-degree hybrid circuit is connected to the input terminal of the second filter.

11. The electronic circuit device as claimed in claim 10, further comprising a first mixer having an output terminal connected to the input terminal of the first filter, and a second mixer having an output terminal connected to the input terminal of the second filter.
